(19) United States
(12) Patent Application Publication
(10) Pub. No.: US 2015/0097531 A1
(43) Pub. Date: Apr. 9, 2015

(54) SYSTEM AND METHOD FOR CONTROLLING NETWORKED, GRID-LEVEL ENERGY STORAGE DEVICES

(71) Applicants: Warren Powell, Princeton, NJ (US); Daniel Salas, New York, NY (US)

(72) Inventors: Warren Powell, Princeton, NJ (US); Daniel Salas, New York, NY (US)

(73) Assignee: THE TRUSTEES OF PRINCETON UNIVERSITY, Princeton, NJ (US)

(21) Appl. No.: 14/506,246

(22) Filed: Oct. 3, 2014

Related U.S. Application Data
(60) Provisional application No. 61/886,435, filed on Oct. 3, 2013.

(51) Int. Cl. H02J 7/00; H02J 7/35; G01R 31/36

(52) U.S. Cl. CPC H02J 7/007; G01R 31/3606; H02J 7/35
USPC 320/134

(57) ABSTRACT

A method for controlling an energy storage system coupled to a power grid is disclosed. The method includes providing a processor configured to receive current state information including energy level in the storage system, current energy price information and current load information from the power grid. A scalar piecewise linear value function is iteratively solved using the current state information and generating charge/discharge control information. The charge/discharge control information is transmitted to the energy storage system.

### CROSS-REFERENCE TO PRIOR FILED APPLICATIONS

This application claims the benefit of U.S. Provisional Application No. 61/886,435 filed Oct. 3, 3013, which is incorporated herein in its entirety.

### GOVERNMENT RIGHTS IN THIS INVENTION

This invention was made with government support under CMMI-0856153 awarded by the NSF. The government has certain rights in this invention.

### TECHNICAL FIELD

The present disclosure generally relates to the field of energy storage and in more particular to systems and methods for controlling networked, grid-level energy storage devices.

### BACKGROUND OF THE INVENTION

One of the main challenges in developing solar and wind energy storage strategies is to maximize the allocation efficiency of the storage devices, which may be charged or discharged at each point in time. These devices are generally treated as simple black-box models, which do not explicitly reflect the underlying physicochemical principles. In the case of wind energy, the most significant difficulty comes in the form of uncertainty. An efficient approach is needed to control for battery system control where the energy may be supplied by a wind farm or directly from the grid.

### BRIEF SUMMARY OF THE INVENTION

A method for controlling an energy storage system coupled to a power grid is disclosed. The method includes providing a processor configured to receive current state information including energy level in the storage system, current energy price information and current load information from the power grid. A scalar piecewise linear value function is iteratively solved using the current state information and generating charge/discharge control information. The charge/discharge control information is transmitted to the energy storage system.

The method may also include initializing the scalar piecewise linear value function. The method may also include updating the scalar piecewise linear value function on each iteration. The method may also include determining the effect of marginal value of energy in the storage system. The method may also include determining the marginal value of energy in the storage system is repeated over a planning horizon. The method may also include stepping back in time to update the marginal value of energy. The method may also include smoothing the marginal value into the scalar piecewise linear value function. The method may also include updating the scalar piecewise linear value function to maintain concavity. The method may also include updating the charge/discharge state of the energy storage system based on the charge/discharge control information.

A system for controlling an energy storage system coupled to a power grid is also disclosed. The system includes a processor configured to receive current state information including energy level in the storage system, current energy price information and current load information from the power grid. The processor is configured to iteratively solve a scalar piecewise linear value function using the current state information and generating charge/discharge control information. The processor is also configured to transmit the charge/discharge control information to the energy storage system.

The processor may be configured to initialize the scalar piecewise linear value function. The processor may be configured to update the scalar piecewise linear value function on each iteration. The processor may be configured to determine the effect of marginal value of energy in the storage system. The processor may be configured to determine the marginal value of energy in the storage system is repeated over a planning horizon. The processor may be configured to step back in time to update the marginal value of energy. The processor may be configured to smooth the marginal value into the scalar piecewise linear value function. The processor may be configured to update the scalar piecewise linear value function to maintain concavity. The processor may be configured to update the charge/discharge state of the energy storage system based on the charge/discharge control information.

A computer-readable medium having stored thereon a computer program for execution by a processor configured to perform a method for controlling an energy storage system coupled to a power grid is disclosed. The method includes providing a processor configured to receive current state information including energy level in the storage system, current energy price information and current load information from the power grid. A scalar piecewise linear value function is iteratively solved using the current state information and generating charge/discharge control information. The charge/discharge control information is transmitted to the energy storage system.

### BRIEF DESCRIPTION OF THE DRAWINGS

FIG. 1 is a block diagram of a grid level power control system including a plurality of renewable energy sources coupled to a power grid and a central computer;

FIG. 2 is a block diagram showing basic operation of the central computer;

FIG. 3 is a block diagram showing operation of the Approximation Dynamic Programming (ADP) approach;

FIGS. 4A-4D are graphs showing how the scalar piecewise linear value function is updated; and

FIG. 5 is a more detailed block diagram showing operation of the Approximation Dynamic Programming (ADP) approach.

### DETAILED DESCRIPTION OF THE INVENTION

The approach disclosed herein is described in the follow paper: D. F. Salas, W. B. Powell, Benchmarking a Scalable Approximation Dynamic Programming Algorithm for Stochastic Control of Multidimensional Energy Storage Problems, attached in Provisional Application No. 61/886,435 and is incorporated herein in its entirety.

Approximation Dynamic Programming (ADP) is used to obtain a practical control policy for a more realistic battery system, by taking into account the uncertainty in supply and demand. A unique feature of the ADP approach is the use of piecewise linear value function approximations, which capture the value of energy stored in each device. In the case of wind energy, the most significant difficulty comes in the form of uncertainty. The ADP approach is used for the control of the battery system where the energy from the grid comes from a mixture of fossil fuels, as well as wind and solar sources. The approach incorporates the effect of battery aging on the storage policy using a parameterized weighted throughput model. The approach identifies near-optimal non-anticipatory policies which capture the stochastic nature of wind and solar energy supply and electricity prices.

The ADP approach is capable of designing time-dependent control policies for a portfolio of energy storage devices distributed across the grid, in the presence of uncertainty in future electricity prices, wind energy supply and electricity load. Important aspects include the specifics of how the value functions in the approximate dynamic programming algorithm are estimated, which allows the method to produce nearly optimal solutions when applied to single storage devices (this is the only problem class for which a provably optimal solution is available) while also scaling too many devices over a grid. Classical algorithms based on dynamic programming (and reinforcement learning) would never be able to scale to handle these high dimensional problems.

The ADP approach may be used for controlling a portfolio of energy storage devices. It may potentially be extended for use with bidding models and battery arbitrage. The algorithm may be applied to other problems that involve storage or inventory, including applications that include managing inventories of spare parts, cash in a mutual fund, inventories of vaccines, pools of equipment (e.g. trucks, containers).

The work is based on literature that demonstrates the effectiveness of approximate dynamic programming for use in high-dimensional stochastic resource allocation problems. Applications of approximate dynamic programming to energy storage are relatively recent, and none of the papers in the literature handle multiple storage devices in a coordinated way. Storage comes in different styles such as pumped-hydro, batteries, ultracapacitors, compressed air energy storage (CAES), flywheels and even load shifting (which is a form of storage). Each type of storage device exhibits different losses, rated energy capacities and rated power capacities, and as a result is best suited to handle variations in specific frequency ranges. Low-loss devices that are more expensive and have lower energy capacities, such as ultracapacitors and lithium-ion batteries, are best suited for pulse power and high frequency fluctuations of smaller amplitude. Pumped-hydro and CAES, which generally incur higher losses, are better suited to handling power delivery over relatively longer timescales. We also note that our method handles temporally fine-grained, time-dependent policies with thousands of time periods.

ADP is an umbrella term for a wide range of algorithmic strategies. The specific implementation used depends on how one approximates the value function using piecewise linear curves that maintain concavity. These curves enable them to be used by commercial linear programming solvers, which is how we can scale to high-dimensional applications (such as many storage devices spread around the grid). The methodology can handle processes that vary by time of day in fine increments (which might produce 1,000 time periods per day). This is enabled in part because the value functions can be stored by time of day (storing 1000 functions for each storage device is feasible with current computing power). The updating methodology also depends on a backpropagation scheme that allows fast communication of behaviors over time.

A sketch of the algorithm is given below:

An ADP algorithm

1. Initialize v̅ₜ⁰∀t ∈ T
2. Set: n = 1.
3. Draw a sample realization ωⁿ.
4. For t = 0,...,T:

(a) Solve: xₜⁿ = arg maxₓ_{ₜ}_{∈X}_{ₜ}
(C(Sₜⁿ, xₜ) + V̅ₜⁿ⁻¹(Sₜ^{x,n})).
(b) Calculate ĉₜⁿ⁺ and ĉₜⁿ⁻ as in (17) and (18).
(c) If t < T, compute: S_{t+Δt}ⁿ = S^{M}(Sₜⁿ, xₜⁿ,W_{t+Δt}ⁿ).

5. For t = T,...,0:

(a) Calculate ûₜⁿ⁺ and ûₜⁿ⁻ as in equation (19).
(b) Update:

v̅_{t-Δt}ⁿ(S_{t-Δt}^{x}) ← CAVE( v̅_{t-Δt} ⁿ⁻¹,\hat{v}ₜⁿ)

6. If n < N, set n = n + 1 and go back to step 3. Else:

Return the VFA ( v̅^{N})ₜ₌₀^{T}.

In step 4a, we solve the optimization problem using a commercial linear programming solver.

Step 4b is computed using:

$$\begin{matrix}{\hat{c}}_{t}^{n +} ( {S}_{t}^{n} ) = \frac{C ( {S}_{t}^{n +} , {x}_{t}^{n +} ) - C ( {S}_{t}^{n} , {x}_{t}^{n} )}{δ R} , & ( 17 ) \\ {\hat{c}}_{t}^{n -} ( {S}_{t}^{n} ) = \frac{C ( {S}_{t}^{n} , {x}_{t}^{n} ) - C ( {S}_{t}^{n -} , {x}_{t}^{n -} )}{δ R} . & ( 18 )\end{matrix}$$

Step 4c is executed by simulating the dynamics of the entire system, which includes a model of the change in energy storage in each device resulting from the decision xₜ, and the evolution of other random information such as electricity prices (known as “locational marginal prices” (LMPs) which are updated every 5 minutes), as well as weather and loads.

Step 5a computes the marginal value of an additional unit of energy stored in each device. This is computed using a backward pass, where the marginal value at time t depends on the marginal value at time t. The basic equation is given by

$${\hat{υ}}_{t}^{n +} ( {S}_{t}^{n} ) = \{ \begin{matrix}{\hat{c}}_{t}^{n +} ( {S}_{t}^{n} ) + {Δ}_{t}^{n +} {\hat{υ}}_{t + Δ t}^{n +} ( {S}_{t + Δ t}^{n} ) & for 0 \leq t < T , \\ {\hat{c}}_{T}^{n +} ( {S}_{T}^{n} ) & otherwise ,\end{matrix} \qquad ( 19 )$$

Step 5b uses a method for updating piecewise linear concave functions called “CAVE.” This is documented in chapter 13 of: W. B. Powell, Approximate Dynamic Programming Solving the curses of dimensionality, John Wiley and Sons, 2011.

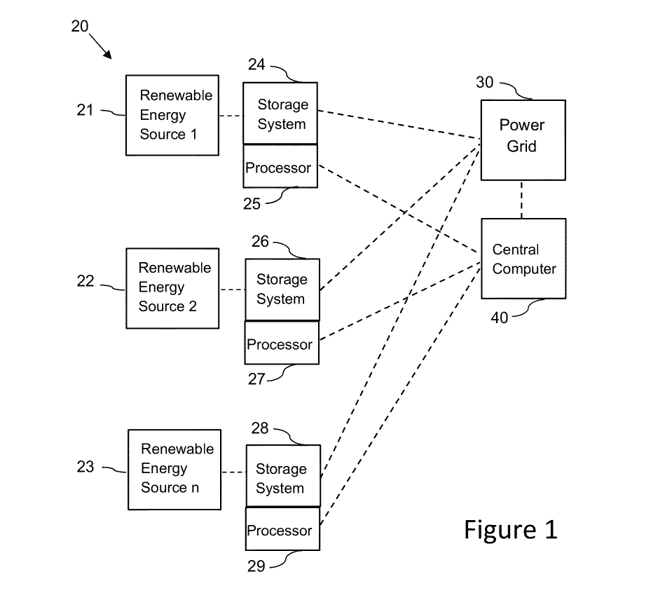

FIG. 1 is a block diagram of a power control system 20 including a plurality of renewable energy sources 21-23 coupled to a power grid 30 and a central computer. The renewable energy sources 21-23 may include a variety of energy sources configured to generate electrical energy from sunlight, wind or other renewable sources. Examples of such devices include solar panels and wind turbines as are well known in the art. In this example, each renewable energy source 21-23 is coupled to a storage system 24, 26, 28 respectively. A typical storage system includes one or more batteries or other electrical energy storage devices and is coupled to the power grid 30 as is well known in the art. It should be understood that other configurations are possible without departing from the scope of this disclosure. For example, multiple renewable energy sources may be coupled to a single storage system. Each storage system also has a storage system processor 25, 27, 29 configured to transmit current charge state information to the central computer. The storage system processor 25, 27, 29 is also configured to receive charge/discharge instructions from the central computer as discussed in detail below.

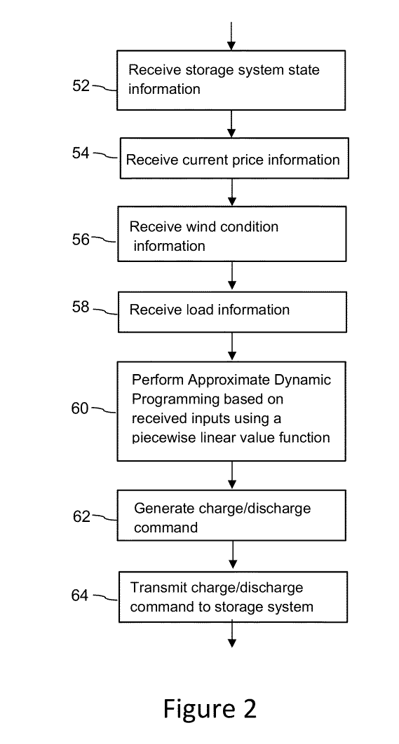

FIG. 2 is a block diagram showing basic operation of the central computer 40. It should be understood that the central computer may be implemented using conventional computer or server hardware and may include an operating system and application software configured to perform approximate dynamic programming as disclosed herein. The central computer 40 is generally configured with memory that has storage location configured for storage of information received from and transmitted to each of the storage systems 24, 26, 28. The central computer 40 and storage systems 24, 26, 28 may be coupled via a communications link as shown by dashed lines in FIG. 1. A variety of communications techniques may be used including a network or the Internet as is well known in the art. In general, the central computer 40 receives several inputs that are used to perform approximate dynamic programming. The central computer 40 then generates charge/discharge information that is transmitted to the storage system. The storage system uses the charge/discharge information to control whether the storage system should continue storing electrical energy or deliver electrical energy to the power grid 30.

Returning to FIG. 2, the central computer 40 receives charge state information from at least one of the storage systems as shown generally by block 52. The central computer 40 receives current price information from a suitable source such as a Regional Transmission Organization, e.g., PJM, as shown generally by block 54. The central computer 40 receives current wind condition information from a meteorological forecasting agency as shown generally by block 56. The central computer 40 receives current load information from the power grid 30 as shown generally by block 58. The central computer 40 uses these inputs that are to perform approximate dynamic programming as discussed in detail below. The central computer 40 then generates charge/discharge information that is transmitted to the storage system. The storage system uses the charge/discharge information to control whether the storage system should continue storing electrical energy or deliver electrical energy to the power grid 30.

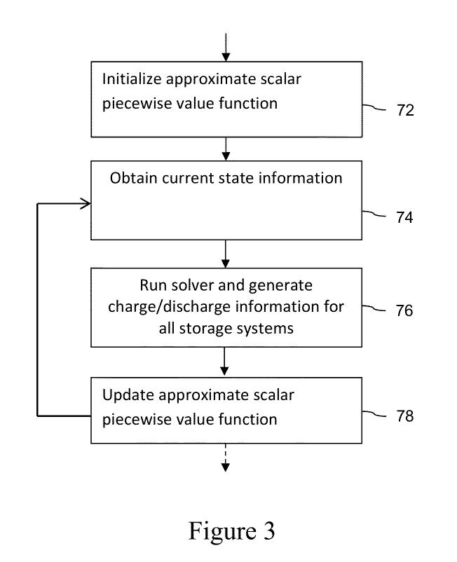

FIG. 3 is a simplified block diagram of approximate dynamic programming. It should be understood that any flowcharts contained herein are illustrative only and that other entry and exit points, time out functions, error checking routines and the like (not shown) would normally be implemented in typical system hardware/software. It is also understood that system hardware/software may run continuously after being launched. Accordingly, any beginning and ending points are intended to indicate logical beginning and ending points of a portion of code or hardware function that can be integrated with other hardware or portions of code and executed as needed. The order of execution of any of the blocks may also be varied without departing from the scope of this disclosure. Implementation of these aspects in hardware and/or software is readily apparent and well within the grasp of those skilled in the art based on the disclosure herein.

An approximate scalar piecewise linear value function is first initialized as shown by block 72. A detailed discussion of a suitable scalar piecewise linear value function is presented in U.S. Provisional Application No. 61/886,435 filed Oct. 3, 3013, which is incorporated herein in its entirety. The current state information is obtained as generally shown by block 74, including e.g., energy price information, current load, current environmental conditions including solar and wind conditions and current charge level of the storage systems. A solver is then run using the state information as inputs to generate charge/discharge information for each storage system as shown by block 76. The charge/discharge information is communicated to each storage system and generally instructs the storage system to storage charge, deliver charge to the grid or to do nothing (neither charge nor discharge). It should be understood that charge/discharge information may include an amount of change or an absolute value. The approximate scalar piecewise linear value function is updated and the process is repeated as shown by block 78.

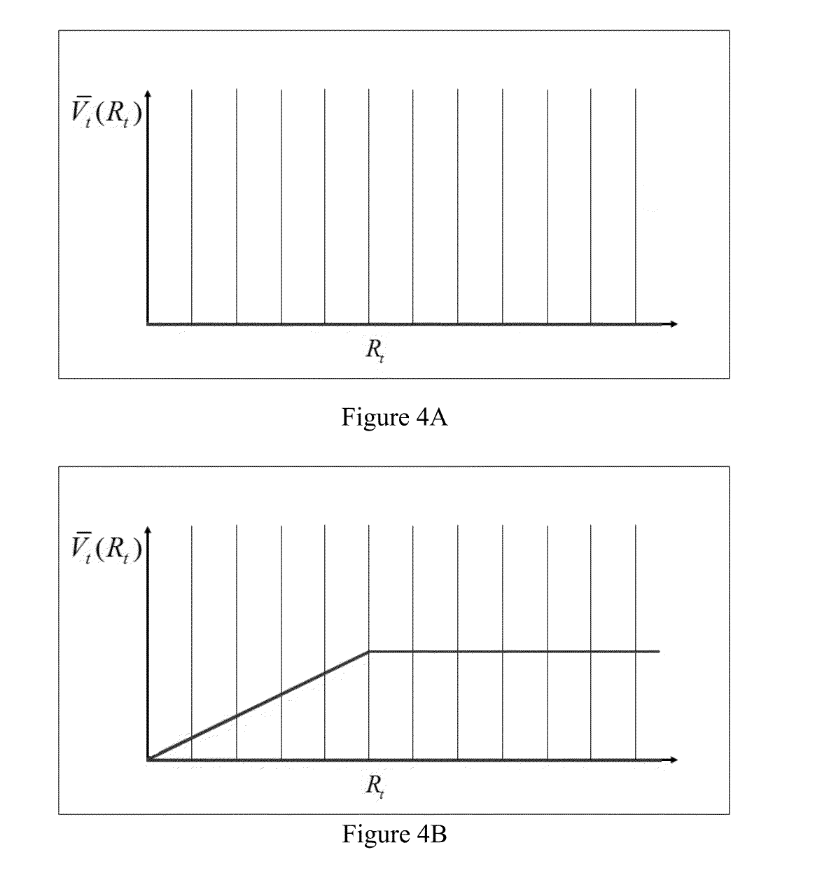

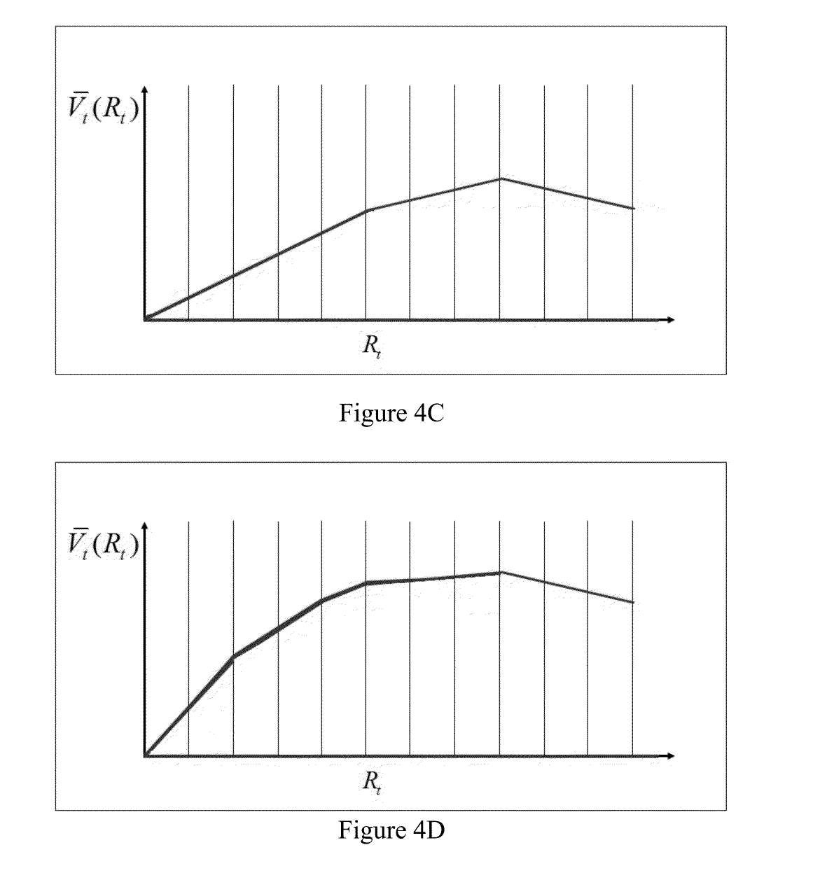

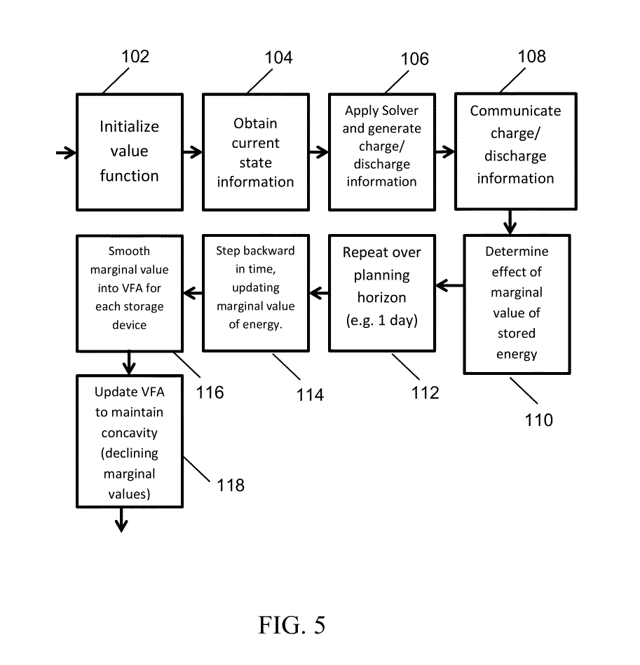

FIGS. 4A-4D are graphs showing how the scalar piecewise linear value function is updated. The X axis shows the charge in the battery. The Y axis shows the approximate scalar piecewise linear value function. The vertical lines represent discrete energy levels in the storage system. In between individual segments the value function is linear. It should be understood that the approach may be carried out with any number of discrete energy levels. FIG. 4A is a graph showing the approximate scalar piecewise linear value function set to zero. FIGS. 4B-4C are graphs showing how the approximate scalar piecewise linear value function is updated with repeated iterations of the approximate dynamic programming shown in FIG. 3.

FIG. 5 is a more detailed block diagram of approximate dynamic programming. In this example, the approximate scalar piecewise linear value function is first initialized as shown by block 102 (see also step 1 of the algorithm disclosed above). Current state information is obtained as generally shown by block 104. As discussed above, this information may include e.g., energy price information, current load, current environmental conditions including solar and wind conditions and current charge level of the storage systems. This generally corresponds to step 3 of the algorithm disclosed above which used a sample realization to run a simulation as opposed to actual state information. A solver is then run using the state information as inputs to generate charge/discharge information for each storage system as shown by block 106 (see also step 4(a) of the algorithm disclosed above). The charge/discharge information is communicated to each storage system as shown by block 108. The charge/discharge generally instructs each storage system to storage charge, deliver charge to the grid or to do nothing (neither charge nor discharge). The effect of marginal value of energy is determined in each storage system as shown by block 110, this is generally implemented as a forward pass (see also step 4(b) and 5(a) of the algorithm disclosed above). This process is repeated over the planning horizon, e.g., 1 day as shown by block 112, this is generally implemented as a backwards pass (see also 5(a) of the algorithm disclosed above). The process is stepped back in time, updating the marginal value of energy as shown by block 114. The marginal value is then smoothed into the approximate scalar piecewise linear value function for each storage system as shown by block 116. The approximate scalar piecewise linear value function is updated to maintain concavity (declining marginal values) as shown by block 118.

The approach disclosed herein has been tested on a set of deterministic and stochastic energy storage problems with one storage device (available at castlelab.princeton.edu/datasets.htm). The algorithm was shown to be within 0.08% of optimal in deterministic problems and within 1.34% in stochastic ones. The algorithm was also tested on multidimensional problems but a benchmark solution cannot be obtained. However, the algorithm was able to learn fairly sophisticated behavior in these cases.

There are a number of publications on the general topic of energy storage. They are cited in D. F. Salas, W. B. Powell, “Benchmarking a Scalable Approximation Dynamic Programming Algorithm for Stochastic Control of Multidimensional Energy Storage Problems.” Some of these also use algorithms that can be classified under the broad umbrella of approximate dynamic programming. The approach disclosed herein is the first to be able to handle multiple, grid-level storage devices. This implementation, drawing on indexed, piecewise linear value functions updated with the CAVE algorithm and a backward pass procedure (which accelerates convergence), is unique for this problem class.

The approach may be implemented in software that can be licensed to companies that are implementing grid-level storage, or storage devices designed to be paired with solar or wind installations. There is growing interest in controllers that can run on the cloud, which would enable the use of sophisticated solvers required by this algorithm.

The approach is computationally fast, scales to multiple storage devices, handles heterogeneous storage devices with different losses and power ratings, produces time-dependent policies (that is, the decisions may be different at different times of day, even if the state of the network is the same). For example, we show in our experimental work that the logic will make rapid charge-discharge decisions of small amounts of energy for low-loss storage devices (this handles the fast changes in electricity prices), while using larger devices with higher losses to respond to slower patterns (such as hour of day demand patterns).

The approach may be implemented as part of an online controller. In such systems grid level storage operates through signals sent from a central server. Such systems are often operated by a large independent system operator such as PJM Interconnections, or from a central server managing a single storage device.

The approach may also be used in the planning of the location and sizing of one or more storage devices. This is the most likely initial commercial use, since storage is an emerging technology, there is a need to configure new systems. The disclosed logic can be used to help determine the right size, and to compare different battery chemistries.

The references listed herein are also part of the application and are incorporated by reference in their entirety as if fully set forth herein. It should be understood that many variations are possible based on the disclosure herein. Although features and elements are described above in particular combinations, each feature or element can be used alone without the other features and elements or in various combinations with or without other features and elements. The methods or techniques provided herein may be implemented in a computer program, software, or firmware incorporated in a non-transitory computer-readable storage medium for execution by a general purpose computer or a processor. Examples of computer-readable storage mediums include a read only memory (ROM), a random access memory (RAM), a register, cache memory, semiconductor memory devices, magnetic media such as internal hard disks and removable disks, magneto-optical media, and optical media such as CD-ROM disks, and digital versatile disks (DVDs).

What is claimed is:

1) A method for controlling an energy storage system coupled to a power grid, the method comprising:
providing a processor configured to receive current state information including energy level in the storage system, current energy price information and current load information from the power grid;
iteratively solving a scalar piecewise linear value function using the current state information and generating charge/discharge control information; and
transmitting the charge/discharge control information to the energy storage system.

2) The method of claim 1, further comprising initializing the scalar piecewise linear value function.

3) The method of claim 1, further comprising updating the scalar piecewise linear value function on each iteration.

4) The method of claim 1, further comprising determining the effect of marginal value of energy in the storage system.

5) The method of claim 4, wherein determining the marginal value of energy in the storage system is repeated over a planning horizon.

6) The method of claim 1, further comprising stepping back in time to update the marginal value of energy.

7) The method of claim 1, further comprising smoothing the marginal value into the scalar piecewise linear value function.

8) The method of claim 1, further comprising updating the scalar piecewise linear value function to maintain concavity.

9) The method of claim 1, further comprising updating the charge/discharge state of the energy storage system based on the charge/discharge control information.

10) A system for controlling an energy storage system coupled to a power grid, the system comprising:
a processor configured to receive current state information including energy level in the storage system, current energy price information and current load information from the power grid;
the processor being configured to iteratively solve a scalar piecewise linear value function using the current state information and generating charge/discharge control information; and
The processor being configured to transmit the charge/discharge control information to the energy storage system.

11) The system of claim 10, wherein the processor is configured to initialize the scalar piecewise linear value function.

12) The system of claim 10, wherein the processor is configured to update the scalar piecewise linear value function on each iteration.

13) The system of claim 10, wherein the processor is configured to determine the effect of marginal value of energy in the storage system.

14) The system of claim 13, wherein the processor is configured to determine the marginal value of energy in the storage system is repeated over a planning horizon.

15) The system of claim 10, wherein the processor is configured to step back in time to update the marginal value of energy.

16) The system of claim 10, wherein the processor is configured to smooth the marginal value into the scalar piecewise linear value function.

17) The system of claim 10, wherein the processor is configured to update the scalar piecewise linear value function to maintain concavity.

18) The system of claim 10, wherein the processor is configured to update the charge/discharge state of the energy storage system based on the charge/discharge control information.

19) A computer-readable medium having stored thereon a computer program for execution by a processor configured to perform a method for controlling an energy storage system coupled to a power grid, the method comprising:
providing a processor configured to receive current state information including energy level in the storage system, current energy price information and current load information from the power grid;
iteratively solving a scalar piecewise linear value function using the current state information and generating charge/discharge control information; and
transmitting the charge/discharge control information to the energy storage system.
